(19) United States
(12) Patent Application Publication
(10) Pub. No.: US 2023/0097999 A1
(43) Pub. Date: Mar. 30, 2023

(54) SHOWERHEAD AND SUBSTRATE PROCESSING APPARATUS INCLUDING THE SAME

(71) Applicant: EUGENE TECHNOLOGY CO., LTD., Yongin-si (KR)

(72) Inventors: Doo-Yeol RYU, Yongin-si (KR); Sang Don LEE, Yongin-si (KR); Wan Suk OH, Yongin-si (KR); Ho Min CHOI, Yongin-si (KR); Sung Gyun SON, Yongin-si (KR); Hyo Jin AHN, Yongin-si (KR)

(73) Assignee: EUGENE TECHNOLOGY CO., LTD., Yongin-si (KR)

(21) Appl. No.: 17/953,817

(22) Filed: Sep. 27, 2022

(30) Foreign Application Priority Data
Sep. 27, 2021 (KR) 10-2021-0127517

(51) Int. Cl. C23C 16/455; B05B 1/18; C23C 16/458

(52) U.S. Cl. CPC C23C 16/45565; B05B 1/185; C23C 16/4583

(57) ABSTRACT

According to an embodiment of the present invention, a substrate processing apparatus including: a chamber in which a process is performed on a substrate; a susceptor installed in the chamber to support the substrate; and a showerhead installed above the susceptor, and the showerhead includes: a plurality of inner injection holes defined in an inner area corresponding to a portion above the substrate and injecting a reaction gas downward; and a plurality of outer injection holes defined in an outer area corresponding to a portion outside the inner area and injecting an inert gas along an inner wall of the chamber.

### TECHNICAL FIELD

The present invention relates to a showerhead and a substrate processing apparatus, and more particularly, to a showerhead and a substrate processing apparatus, which may prevent a reaction gas from being adsorbed to an inner component or an inner wall of the chamber.

### BACKGROUND

A semiconductor device includes a plurality of layers on a silicon substrate, and the layers are deposited on the substrate through a deposition process. The deposition process has several issues that are important to evaluate the deposited layers and select a deposition method.

First, one of the issues is ‘quality’ of each of the deposited layers. The ‘quality’ represents composition, contamination levels, defect density, and mechanical and electrical properties. The composition of the deposited layer may be changed according to deposition conditions. This is very important to obtain a specific composition.

Second, another of the important issues is a uniform thickness across a wafer. Particularly, a thickness of a layer deposited on a pattern having a nonplanar shape with a stepped portion is extremely important. Here, whether the thickness of the deposited layer is uniform may be determined through a step coverage which is defined as a ratio obtained by dividing a minimum thickness of the layer deposited on the stepped portion by a thickness of the layer deposited on a top surface of the pattern.

Another issue related to the deposition may be a filling space. The filling space may include gap filling, which allows an insulating layer including an oxide layer to be filled between metal lines. A gap is provided to physically and electrically isolate the metal lines from each other.

Among the issues, uniformity is one of the important issues related to the deposition process. A non-uniform layer may cause high electrical resistance on the metal lines to increase possibility of mechanical damage.

The deposition process is performed in a chamber in which a substrate is disposed. The deposition process is performed by supplying a reaction gas into the chamber through a showerhead installed above the substrate in a state in which the substrate is supported on a susceptor. Here, a portion of the reaction gas is adsorbed to an inner component or an inner wall of the chamber. When the adsorption is continuously generated, a portion of the adsorbed material may be separated and introduced to the substrate. Also, when a thickness of the adsorbed material is increased, heat distribution in the chamber may be distorted to cause a non-uniform thin layer.

### SUMMARY

The present invention provides a showerhead and a substrate processing apparatus, which may prevent a reaction gas from being adsorbed to an inner component or an inner wall of the chamber.

The present invention also provides a showerhead and a substrate processing apparatus, which may secure a uniform thin layer.

Further another object of the present invention will become evident with reference to following detailed descriptions and accompanying drawings.

According to an embodiment of the present invention, a substrate processing apparatus includes: a chamber in which a process is performed on a substrate; a susceptor installed in the chamber to support the substrate; and a showerhead installed above the susceptor, and the showerhead includes: a plurality of inner injection holes defined in an inner area corresponding to a portion above the substrate and injecting a reaction gas downward; and a plurality of outer injection holes defined in an outer area corresponding to a portion outside the inner area and injecting an inert gas along an inner wall of the chamber.

The showerhead may have an accommodation space recessed from a top surface thereof, and the accommodation space may be partitioned into an inflow space disposed at an upper portion of the accommodation space and a diffusion space disposed at a lower portion of the accommodation space by a block plate installed in the accommodation space. The inflow space may have an inner inflow space which corresponds to the inner injection holes and through which the reaction gas is introduced and an outer inflow space which corresponds to the outer injection holes and through which the inert gas is introduced.

The reaction gas and the inert gas may be diffused in the diffusion space.

The block plate may have a ring-shaped partition wall for partitioning the inflow space into the inner inflow space and the outer inflow space.

The substrate processing apparatus may further include a chamber lid installed on the showerhead to isolate the accommodation space from the outside, and the chamber lid may have an inner gas port communicating with the inner inflow space and an outer gas port communicating with the outer inflow space.

The inner area may have a size corresponding to that of the substrate.

According to an embodiment of the present invention, a showerhead installed above a substrate includes: a plurality of inner injection holes defined in an inner area corresponding to a portion above the substrate and injecting a reaction gas downward; and a plurality of outer injection holes defined in an outer area corresponding to a portion outside the inner area and injecting an inert gas along an inner wall of the chamber.

### BRIEF DESCRIPTION OF THE DRAWINGS

FIG. 1 is a schematic cross-sectional view illustrating a substrate processing apparatus according to an embodiment of the present invention;

FIG. 2 is a view illustrating a showerhead illustrated in FIG. 1;

FIG. 3 is a view illustrating a block plate illustrated in FIG. 1;

FIG. 4 is a view illustrating a chamber lid illustrated in FIG. 1;

FIG. 5 is a view illustrating a gas flow in the substrate processing apparatus illustrated in FIG. 1;

FIG. 6 is a graph representing an amount of impurities according to a supply amount of an inert gas based on a substrate processing result according to an embodiment of the present invention; and

FIG. 7 is a graph representing a deviation of a thickness of a thin layer according to a supply amount of an inert gas based on the substrate processing result according to an embodiment of the present invention.

### DETAILED DESCRIPTION

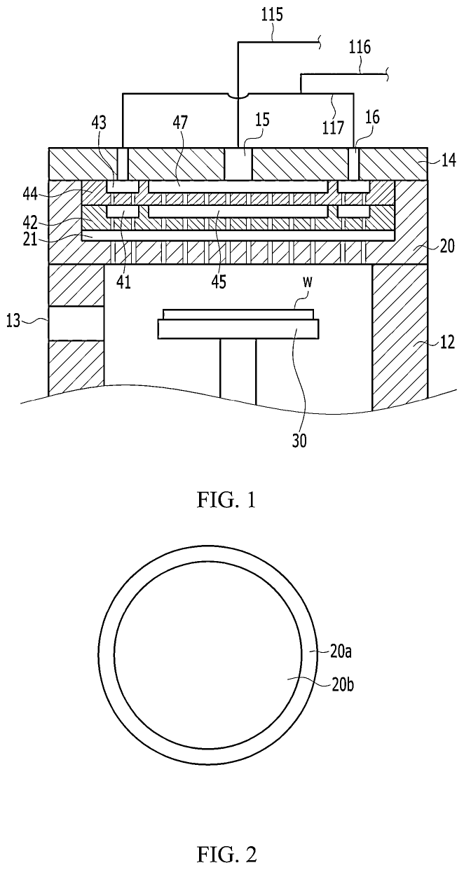

Hereinafter, preferred embodiments of the present invention will be described in more detail with reference to FIGS. 1 to 7. The present invention may, however, be embodied in different forms and should not be constructed as limited to the embodiments set forth herein. Rather, these embodiments are provided so that this invention will be thorough and complete, and will fully convey the scope of the present invention to those skilled in the art. In the figures, the dimensions of layers and regions are exaggerated for clarity of illustration.

Although a deposition apparatus is exemplarily described below, embodiments of the present invention are not limited thereto. For example, the present invention may be applied to various processes for processing a substrate by using a reaction gas.

FIG. 1 is a schematic cross-sectional view illustrating a substrate processing apparatus according to an embodiment of the present invention. As illustrated in FIG. 1, a substrate processing apparatus 10 includes a chamber 12 and a chamber lid 14. The chamber 12 has an opened upper portion and a passage 13 through which a substrate W is loaded and unloaded. The substrate W may be loaded into the chamber 12 through the passage 13, and a gate valve (not shown) may be installed on the outside of the passage 13 to open or close the passage 13.

The chamber 12 has an inner process space in which a process is performed on the substrate W, and the process space has an approximately circular cylinder shape. However, as described above, since the passage 13 is provided for loading or unloading the substrate W, the process space may be asymmetric with respect to a center thereof, and this may cause non-uniformity of a process. However, as an inert gas that will be described later flows along an inner wall of the chamber 12 to block a circumference of the substrate W from the outside, a virtual process space may be provided. Thus, as an effect in which the asymmetric factor affects the process is minimized, the process space may be adjusted to approximate symmetry.

The chamber lid 14 closes and opens the opened upper portion of the chamber 12. When the chamber lid 14 closes the opened upper portion of the chamber 12, the chamber 12 and the chamber lid 14 defines an inner space that is closed from the outside. The chamber lid 14 has a gas port 15 and 16 communicating with upper inflow spaces 43 and 47 of a showerhead 20 that will be described later, the reaction gas is supplied to an inner inflow space 47 through the gas port 15, and the inert gas is supplied to an outer inflow space 43 through the gas port 16.

A susceptor 30 is installed in the chamber 12, and the substrate W is disposed on the susceptor 30. The susceptor 30 may include a heater (not shown), and the heater may heat the substrate W at a process temperature through a current applied from an external power.

FIG. 2 is a view illustrating the showerhead illustrated in FIG. 1. As illustrated in FIGS. 1 and 2, the showerhead 20 is connected to a lower portion of the chamber lid 14 and includes an injection part 20b having a flat plate shape and a flange part 20a installed outside the injection part 20b and fixed to the chamber lid 14.

The injection part 20b is spaced apart from the chamber lid 14, and an accommodation space is defined between the chamber lid 14 and the injection part 20b. The injection part 20b has a plurality of injection holes, and the reaction gas and the inert gas, which will be described later, are injected through the injection holes. The reaction gas may include precursor gases such as silane (SiH₄) or dichlorosilane (SiH₂Cl₂). Also, the reaction gas may include dopant source gases such as diborane (B₂H₆) or phosphine (PH₃). The inert gas may include nitrogen (N₂) or a predetermined different inert gas.

The reaction gas reacts with the substrate W to perform a process and then is discharged to the outside through an exhaust port (not shown) installed below the susceptor 30. The exhaust pump (not shown) may be provided to forcedly discharge the reaction gases.

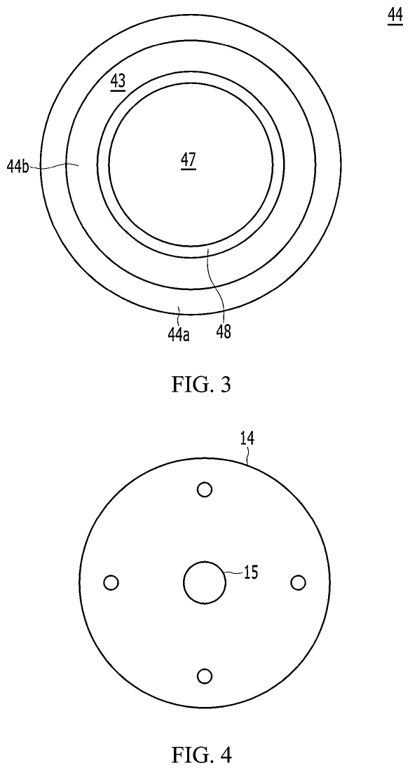

FIG. 3 is a view illustrating a block plate illustrated in FIG. 1. As illustrated in FIG. 1, one pair of block plates have the same structure and shape and installed in the accommodation space of the showerhead 20. Alternatively, the block plates may have different structures and shapes as long as a function described below is realized, and three or more block plates may be installed unlike the embodiment.

As illustrated in FIG. 1, the block plates 42 and 44 are installed in the accommodation space of the showerhead 20, and the accommodation space is partitioned into the upper inflow spaces 43 and 47, lower inflow spaces 41 and 45, and a diffusion space 21 by the block plates 42 and 44. Although spaces for the reaction gas and the inert gas are not partitioned in the diffusion space 21 in the embodiment, the spaces for diffusing the reaction gas and the inert gas may be partitioned to restrict diffusion.

As illustrated in FIG. 3, the block plate 44 includes a plate 44b having a flat plate shape and a flange 44a installed outside the plate 44b and fixed to the flange part 20a of the showerhead 20. The plate 44b is spaced apart from the chamber lid 14 and the injection part 20b, and the block plate 42 is also spaced apart from the chamber lid 14 and the injection part 20b. Thus, the diffusion space 21 is formed between the block plate 42 and the injection part 20b, the lower inflow spaces 41 and 45 are formed above the block plate 42, and the upper inflow spaces 43 and 47 are formed above the block plate 44.

The plate 44b has a plurality of injection holes, and the reaction gas and the inert gas introduced into the upper inflow spaces 43 and 47 may move to the lower inflow spaces 41 and 45 through the injection holes and then move to the diffusion space 21 through the plurality of injection holes defined in the block plate 42, which will be described later.

A partition wall 48 having a ring shape is installed on a top surface of the plate 44b and contacts the chamber lid 14 to partition the upper inflow spaces 43 and 47 into the outer inflow space 43 and the inner inflow space 47.

FIG. 4 is a view illustrating the chamber lid illustrated in FIG. 1. The chamber lid 14 has the inner gas port 15 and the outer gas port 16. The inner gas port 15 is disposed at a center of the chamber lid 14, and the outer gas ports 16 are arranged at an equal angle of 90° around the inner gas port 15. Unlike the embodiment, five or more or three or less outer gas ports 16 may be provided. Here, the outer gas ports 16 may be arranged at an equal angle. The inner gas port 15 communicates with the inner inflow space 47, and the reaction gas is introduced to the inner inflow space 47 through the inner as port 15. The outer gas port 16 communicates with the outer inflow space 42, and the inert gas is introduced to the outer inflow space 43 through the outer gas port 16.

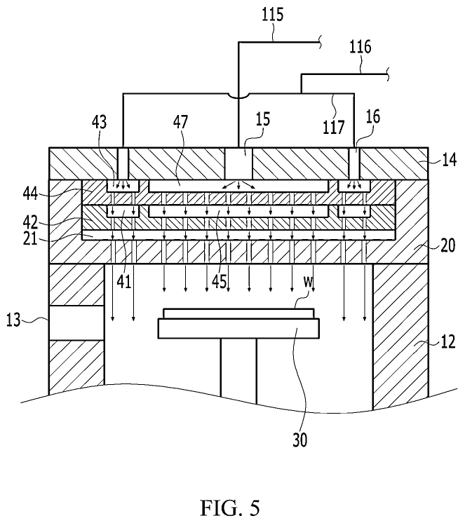

FIG. 5 is a view illustrating a gas flow in the substrate processing apparatus illustrated in FIG. 1. Hereinafter, a deposition process through the showerhead will be described with reference to FIGS. 1 and 5.

Firstly, the reaction gas is introduced to the inner inflow space 47 through the inner gas port 15 and then moves to the diffusion space 21 through the inner inflow space 45, and the inert gas is introduced to the outer inflow space 43 through the outer gas port 16 and then moves to the diffusion space 21 through the outer inflow space 41.

The injection part 20b of the showerhead 20 may be distinguished into an inner area and an outer area. The inner area represents a circular space disposed above the substrate W, and the outer area represents a ring-shaped space disposed at a circumference of the inner area.

The reaction gas in the diffusion space 21 is injected to an upper portion of the substrate W through the injection holes defined in the inner area and deposited onto the substrate. The inert gas in the diffusion space 21 may be injected through the injection holes defined in the outer area and flows along the inner wall of the chamber 12 to block the reaction gas from moving toward the inner wall of the chamber and block the circumference of the substrate W from the outside, thereby providing the virtual process space as described above. Also, as the effect in which the asymmetric factor affects the process is minimized, the process space may be adjusted to approximate symmetry.

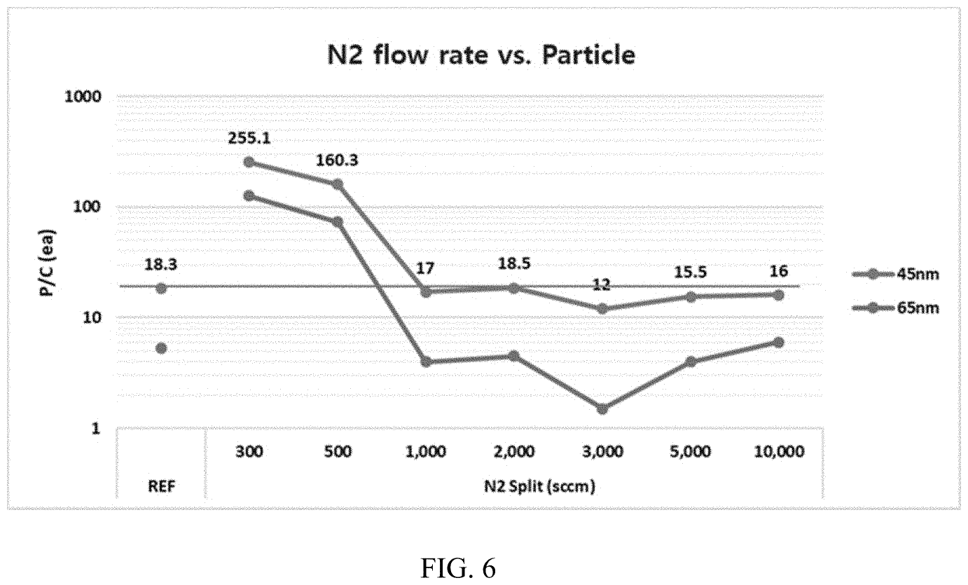

FIG. 6 is a graph representing an amount of impurities according to a supply amount of the inert gas based on a substrate processing result according to an embodiment of the present invention. As illustrated in FIG. 6, when the reaction gas moves to the inner wall of the chamber, the reaction gas is adsorbed to the inner wall of the chamber, and the adsorbed material is separated from the inner wall of the chamber to cause pollution of the substrate W. However, when the inert gas flows along the inner wall of the chamber, a movement of the reaction gas toward the inner wall of the chamber may be blocked, and thus impurities may be fundamentally blocked.

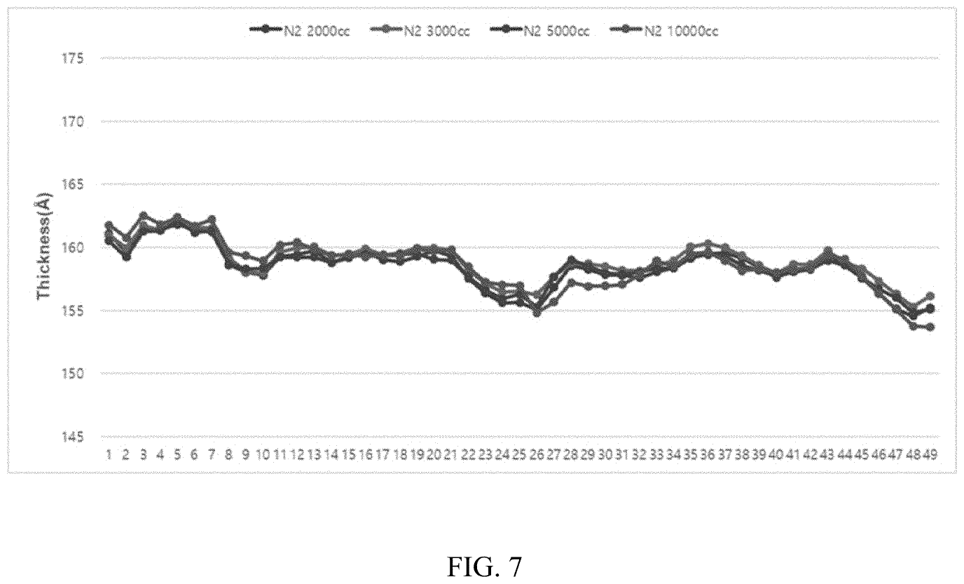

FIG. 7 is a graph representing a deviation of a thickness of a thin layer according to a supply amount of the inert gas based on the substrate processing result according to an embodiment of the present invention. When the inert gas flows along the inner wall of the chamber, the approximately symmetric virtual processing space may be provided by blocking the circumference of the substrate W from the outside through the inert gas, and deposition uniformity may be secured as illustrated in FIG. 7.

The reaction gas and the inert gas may be diffused in the diffusion space 21. Although the reaction gas and the inert gas may be slightly mixed in the diffusion space 21 according to injection pressures thereof, this does not represent complete mixture. Particularly, occupied areas of the reaction gas and the inert gas in the diffusion space 21 may be varied in size according to a pressure difference thereof. Through this, a distribution of the injection holes for injecting the reaction gas and the injection holes for injecting the inert gas may be adjusted.

According to the embodiment of the present invention, the reaction gas may be prevented from being adsorbed to the inner component or the inner wall of the chamber by injecting the inert gas along the inner wall of the chamber. Particularly, since the reaction gas and the inert gas are simultaneously diffused in the showerhead and then injected, the reaction gas and the inert gas may be injected with the uniform pressure.

Although the present invention is described in detail with reference to the exemplary embodiments, the invention may be embodied in many different forms. Thus, technical idea and scope of claims set forth below are not limited to the preferred embodiments.

What is claimed is:

1. A substrate processing apparatus comprising:
a chamber in which a process is performed on a substrate;
a susceptor installed in the chamber to support the substrate; and
a showerhead installed above the susceptor,
wherein the showerhead comprises:
a plurality of inner injection holes defined in an inner area corresponding to a portion above the substrate and configured to inject a reaction gas downward; and
a plurality of outer injection holes defined in an outer area corresponding to a portion outside the inner area and configured to inject an inert gas along an inner wall of the chamber.

2. The substrate processing apparatus of claim 1, wherein the showerhead has an accommodation space recessed from a top surface thereof, and the accommodation space is partitioned into an inflow space disposed at an upper portion of the accommodation space and a diffusion space disposed at a lower portion of the accommodation space by a block plate installed in the accommodation space, and
the inflow space has an inner inflow space which corresponds to the inner injection holes and through which the reaction gas is introduced and an outer inflow space which corresponds to the outer injection holes and through which the inert gas is introduced.

3. The substrate processing apparatus of claim 2, wherein the reaction gas and the inert gas are diffused in the diffusion space.

4. The substrate processing apparatus of claim 2, wherein the block plate has a ring-shaped partition wall configured to partition the inflow space into the inner inflow space and the outer inflow space.

5. The substrate processing apparatus of claim 1, further comprising a chamber lid installed on the showerhead to isolate the accommodation space from the outside,
wherein the chamber lid has an inner gas port communicating with the inner inflow space and an outer gas port communicating with the outer inflow space.

6. The substrate processing apparatus of claim 1, wherein the inner area has a size corresponding to that of the substrate.

7. A showerhead installed above a substrate, comprising:
a plurality of inner injection holes defined in an inner area corresponding to a portion above the substrate and configured to inject a reaction gas downward; and
a plurality of outer injection holes defined in an outer area corresponding to a portion outside the inner area and configured to inject an inert gas along an inner wall of the chamber.

8. The showerhead of claim 7, wherein the showerhead has an accommodation space recessed from a top surface thereof, and the accommodation space is partitioned into an inflow space disposed at an upper portion of the accommodation space and a diffusion space disposed at a lower portion of the accommodation space by a block plate installed in the accommodation space, and
the inflow space has an inner inflow space which corresponds to the inner injection holes and through which the reaction gas is introduced and an outer inflow space which corresponds to the outer injection holes and through which the inert gas is introduced.
